(19) United States
(12) Patent Application Publication
(10) Pub. No.: US 2019/0388912 A1
(43) Pub. Date: Dec. 26, 2019

(54) Dispensing Nozzle for a Coater

(71) Applicant: SUSS MicroTec Lithography GmbH, Garching (DE)

(72) Inventor: Mekias KADER, Garching (DE)

(21) Appl. No.: 16/440,080

(22) Filed: Jun. 13, 2019

(30) Foreign Application Priority Data
Jun. 21, 2018 (NL) 2021163

(51) Int. Cl. B05B 1/30; H01L 21/67

(52) U.S. Cl. CPC B05B 1/304; H01L 21/67017

(57) ABSTRACT

A dispensing nozzle for applying a coating to a substrate has a valve seat, a valve element adapted for being displaced between a closed position in which it interacts with the valve seat so as to close a connection between a coating material inlet and a coating material outlet of the dispensing nozzle, and an open position in which this connection is open. Further, a retraction element adapted for being displaced between a forward position and a rearward position is provided, the retraction element being in fluid communication with a dispensing channel of the dispensing nozzle downstream of the valve element.

### CROSS-REFERENCE TO RELATED APPLICATIONS AND PRIORITY

This patent application claims priority from NL Patent Application No. 2021163 filed Jun. 21, 2018, which is herein incorporated by reference in its entirety.

### FIELD OF THE INVENTION

The invention relates to a dispensing nozzle for applying a coating to a substrate, in particular to a wafer.

### BACKGROUND OF THE INVENTION

For producing semiconductor chips and MEMS, it is known to apply to the substrate (wafer) a coating which is processed or aids in processing the substrate. It is important to apply exactly the desired amount of coating to the surface of the wafer as tolerances will result in a thickness of the coating which is higher or lower than it should be. Further, it is to be prevented that a drop of the coating material separates from the dispensing nozzle after the process of applying the coating to the substrate was terminated. Such drop would result in a significant disturbance of the surface of the coating which shall be as plane as possible.

There are various attempts to prevent that a drop of the coating material separates from the dispensing nozzle after the application of the coating has been terminated. A widely used approach is to use a vacuum line which is connected to the dispensing nozzle such that a certain volume of coating material can be “sucked back” into the dispensing nozzle after stopping the process of applying the coating material. This results in the formation of a so-called meniscus at the outlet of the dispensing nozzle, preventing a drop from being formed there and from becoming detached from the dispensing nozzle.

The problem with this solution is that is interferes with a precise metering of the amount of coating material supplied to the substrate as it cannot be controlled properly how much coating material is “sucked back” into the dispensing nozzle at the end of the previous coating step, making it hard to precisely meter the coating material to be applied in the subsequent coating step.

The object of the invention is to improve the accuracy with which coating material can be metered with the dispensing nozzle while at the same time reliably preventing that a drop of coating material unintentionally separates from the dispensing nozzle after termination of a dispensing step.

### BRIEF DESCRIPTION OF THE INVENTION

To this end, the invention provides a dispensing nozzle for applying a coating to a substrate, having a valve seat, a valve element adapted for being displaced between a closed position in which it interacts with the valve seat so as to close a connection between a coating material inlet and a coating material outlet of the dispensing nozzle, and an open position in which this connection is open, and further having a retraction element adapted for being displaced between a forward position and a rearward position, the retraction element being in fluid communication with a dispensing channel of the dispensing nozzle downstream of the valve element, with the retraction element being a diaphragm which on one side is exposed to the dispensing channel.

The invention is based on the basic idea of using a retraction element which mechanically “sucks back” a certain amount of dispensing material downstream of the valve seat. The retraction element allows to very precisely control the amount of coating material which is sucked back into the dispensing nozzle at the end of one dispensing step, making it easy to correctly meter the coating material in the subsequent coating step as exactly the same amount of coating material can be “added” to the subsequent dispensing step by moving the retraction element to the forward position. An additional advantage is that the suck-back is achieved close to the forward end of the dispensing nozzle. This avoids the problems associated with prior art approaches in which the suck-back is made from a remote location which as such is problematic as regards accuracy and furthermore results in problems with materials with tend to outgassing. Because of a diaphragm being used as retraction element, the dispensing channel side of the valve element can be very easily sealed from the “backside” of the valve element.

In one embodiment, the retraction element is arranged laterally of the dispensing channel, in particular in a nozzle body of the dispensing nozzle. This position of the retraction element results in a simple design.

In an alternative embodiment, the retraction element is arranged in the valve element and is in fluid connection with the dispensing channel. This design allows forming the dispensing nozzle with very small dimensions so that two or more dispensing nozzles can be arranged very close to each other on an application device.

A very compact design can be achieved by having the valve element in the form of a sleeve, the diaphragm being clamped to the valve element.

For preventing that coating material contaminates areas of the dispensing nozzle which should not be subjected to the coating material, a sealing element is provided which seals between the valve element and the nozzle body of the dispensing nozzle.

For reliably connecting the diaphragm to the valve element without requiring much space, the sealing element can be screwed into the valve element so as to clamp the diaphragm therein.

In an alternative embodiment, the retraction element is a piston which on one side is exposed to the dispensing channel. As the piston is rigid, it is possible to very precisely control the amount of coating material sucked back into the dispensing nozzle.

Preferably, a retraction control chamber is provided which is operatively connected to the retraction element. The retraction control chamber allows to very easily displace the retraction element between the forward and the rearward position by applying different levels of pressure to the side of the control element exposed to the pressure in the retraction control chamber. As an example, applying a first (positive) pressure to the retraction control chamber results in the retraction element being in the forward position while changing to a second (negative or lower) pressure results in the retraction element being displaced into the rearward position so that a defined volume of coating material is sucked back into the dispensing nozzle. It may be possible to continue using the vacuum line and the associated control elements and control logic of existing dispensing valves, to control the operation of the retraction element or the dispensing valve according to the invention.

According to one embodiment, a retraction control piston is provided which is exposed to the pressure in the retraction control chamber. The retraction control piston is an intermediate element between the retraction element and e.g. a vacuum line and ensures that the retraction element is precisely controlled, in particular in situations where the retraction element is a diaphragm or membrane. The retraction control piston can be mechanically connected to the retraction element.

Preferably, an adjustable retraction abutment is provided for adjusting the maximum stroke of the retraction control piston. The retraction abutment allows adjusting the amount of coating material sucked back into the dispensing nozzle to the particular properties of different coating materials so that the “correct” amount of coating material is sucked back at the end of a dispensing step independent from the particular coating material which is being processed.

The retraction abutment can be a screw or involve a thread and may be adjusted either manually or remotely by using a stepper motor.

According to a preferred embodiment of the invention, a dispensing control chamber is provided which is operatively connected to the valve element. In a manner similar to controlling the movement of the retraction element, the dispensing control chamber is used for controlling the position and the displacement of the valve element. This can be achieved by changing the pressure level in the dispensing control chamber so that the valve element is pressed against the valve seat when the force acting on the valve element towards the valve seat is higher than the force biasing the valve element away from the valve seat, and vice versa.

Preferably, the sealing element is guided on the retraction control piston so that a radial guiding function is provided for the valve element.

Preferably, the retraction control piston is screwed onto a projection of the diaphragm which results in a compact yet reliable connection.

For the valve element as well, an adjustable dispensing abutment may be provided for adjusting the maximum stroke of the valve element. This allows using a very basic control for the pressure level in the dispensing control chamber as the pressure level therein is not necessary for controlling the position of the valve element in the open position. Rather, it is sufficient to use the pressure for displacing the valve element between a fixed closed position (defined by the valve seat) and a fixed (yet adjustable) open position defined by the dispensing abutment.

The dispensing abutment can be in the form of a screw or use a threaded connection which translates a rotation into a translation so that the opening stroke of the valve element can be adapted to the particular properties of different coating materials.

A driving mechanism (such as a steeper motor with a gear) can be provided for adjusting the dispensing abutment in an automated manner based on control signals.

### BRIEF DESCRIPTION OF THE DRAWINGS

The invention will now be described with reference to the enclosed drawings. In the drawings,

FIG. 1 shows a schematic cross section of the dispensing nozzle,

FIG. 2 shows a cross section of the core elements of the dispensing nozzle of FIG. 1,

FIG. 3 shows the valve element used in the dispensing nozzle in a cross-section,

FIG. 4 shows the valve element of FIG. 3 in a perspective view,

FIG. 5 shows the diaphragm used in the dispensing nozzle in a cross section,

FIG. 6 shows the diaphragm of FIG. 5 in a perspective view,

FIG. 7 shows the sealing element used in the dispensing nozzle in a cross section,

FIG. 8 shows the adjustable retraction abutment used in the dispensing nozzle in a cross section,

FIG. 9 shows the adjustable retraction abutment of FIG. 8 in a perspective view.

FIG. 10 shows at an enlarged scale a portion of the dispensing nozzle in a condition when coating material is being dispensed,

FIG. 11 shows the dispensing nozzle of FIG. 10 in a condition in which the dispensing has been shut off,

FIG. 12 shows the dispensing nozzle of FIG. 10 in a condition in which some of the coating material has been sucked back.

### DETAILED DESCRIPTION OF THE INVENTION

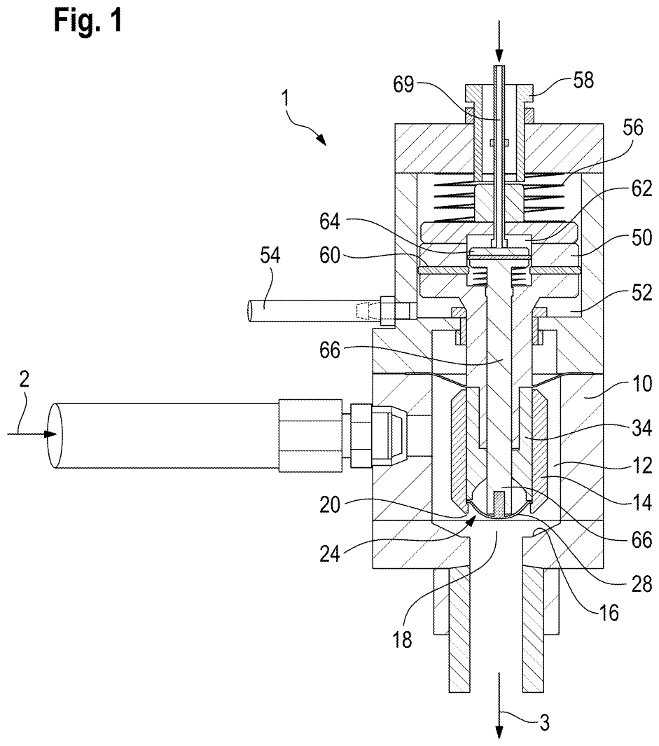

A dispensing nozzle 1 for applying a coating material onto a substrate will now be explained with reference to FIGS. 1 to 9. The dispensing nozzle 1 is in particular suitable for machinery used for the production of semiconductor chips and MEMS.

Dispensing nozzle 1 has a nozzle body 10 provided with a coating material inlet 2 and a coating material outlet 3. Coating material inlet 2 is connected via a tube or other suitable component to a supply of coating material. Coating material outlet 3 can be in the form of a nozzle or other configuration adapted for applying a particular coating material onto a substrate.

In the interior of nozzle body 10, a chamber 12 is provided between the coating material inlet 2 and the coating material outlet 3. Within chamber 12, a valve element 14 is arranged which can cooperate with an annular valve seat 16 which is formed so as to circumscribe a dispensing channel 18 acting as the coating material outlet 3.

The side of the valve seat 16 or the direction towards the valve seat 16 will in the following be referred to as “forward” while the opposite side or direction will be referred to as “rearward”.

Valve element 14 can be displaced between a closed position and an open position. In the closed position, valve element 14 contacts valve seat 16 with its forward annular end. As valve element 14 is sealed with respect to nozzle body 10 (which will be explained in detail below), a connection between coating material inlet 2 and coating material outlet 3 of dispensing nozzle 1 is closed in this position of valve element 14. In the open position, valve element 14 is spaced (in a controllable manner) from valve seat 16 so that the flow connection between coating material inlet 2 and coating material outlet 3 is open. The amount of coating material dispensed with dispensing nozzle 1 through dispensing channel 18 then depends from the pressure with which the coating material is supplied, the viscosity of the coating material, and the stroke of the valve element 14 with which it was lifted from valve seat 16.

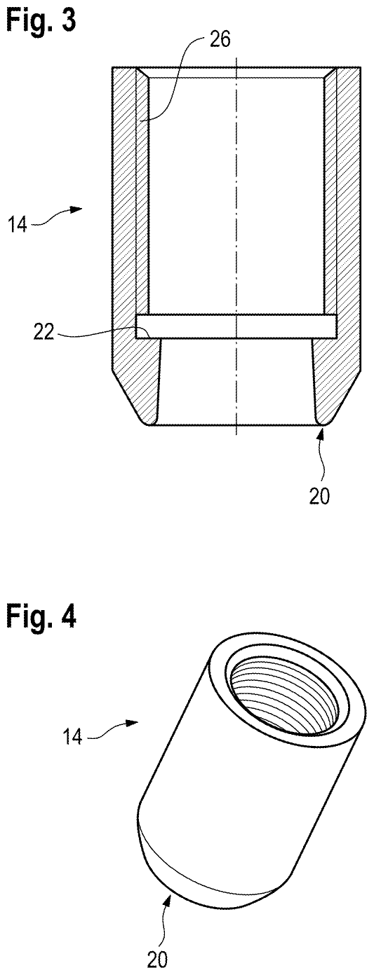

Valve element 14 is a hollow sleeve (please see in particular FIGS. 3 and 4) which has a tapering and rounded end face forward end face 20 adapted for contacting valve seat 16.

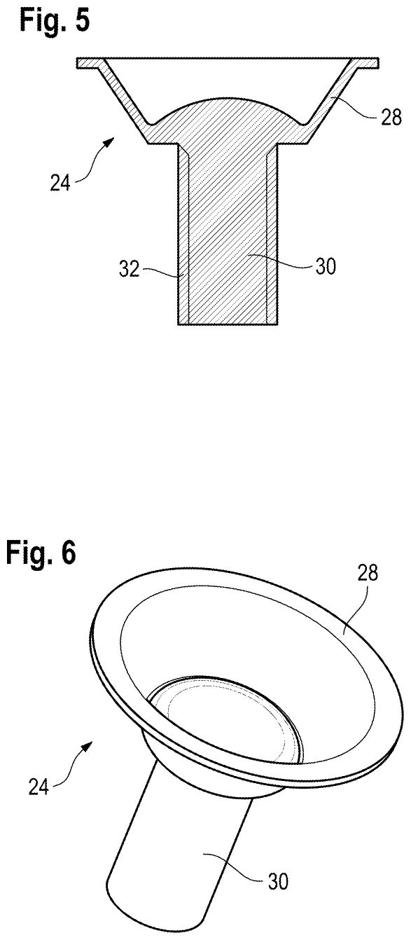

In its interior, valve element 14 has an abutment 22 for a diaphragm 24 (please see in particular FIGS. 5 and 6) arranged in the forward portion of valve element 14. Rearward of abutment 22 (when viewed from end face 20), valve element 14 has an internal thread 26.

Diaphragm 24 has a dish-like forward membrane 28 and a cylindrical protrusion 30 which is connected to the center of membrane 28. A thread 32 is formed on the outer surface of protrusion 30.

Diaphragm 24 is formed from polytetrafluoroethylene (PTFE) or perfluoroalcoxy (PFA). However, other materials can be used as well.

Here, membrane 28 and protrusion 30 are formed in one piece. It is however also possible to form protrusion 30 as a separate piece which is then connected to membrane 28.

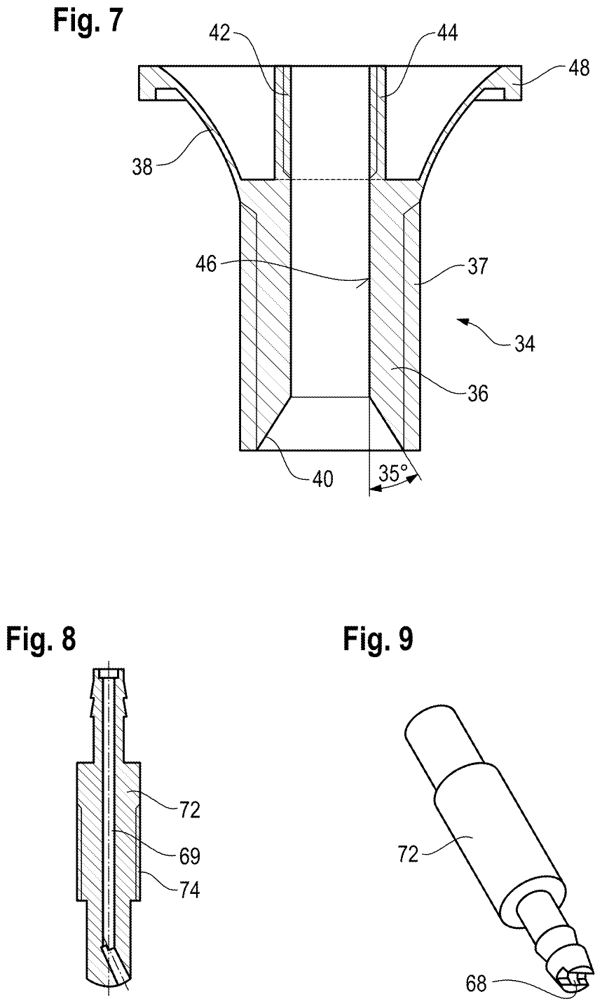

Diaphragm 24 is mounted in the interior of valve element 14 by clamping the outer circumference of membrane 28 against abutment 22 formed in sleeve-like valve element 14. For doing so, a sealing element 34 (please see FIG. 7) is used.

Sealing element 34 is a hollow, generally sleeve-like body with a guiding sleeve 36 at its forward end and a sealing bellows 38 at its rearward end.

Guiding sleeve 36 has an inwardly tapering end face 40 which forms a support surface for membrane 28 of diaphragm 24. On its outer surface, an outer thread 37 is formed.

At its rearward end, guiding sleeve 36 has a control projection 42 which is provided with an outer thread 44.

Guiding sleeve 36 and control projection 42 here form a continuous cylindrical guiding surface 46.

Sealing bellows 38 is provided with an annular connecting reinforcement 48 used for clamping it to nozzle body 10.

Sealing element 34 can be formed from the same materials as diaphragm 24, in particular PTFE. However, other materials can be used as well.

By screwing guiding sleeve 36 with its thread 37 into thread 26 of valve element 14, the outer circumference of membrane 28 is clamped against abutment 22. Protrusion 30 projects into the interior space of valve element 14.

Annular connecting reinforcement 48 of sealing bellows 38 is clamped between two portions of nozzle body 10 is a tight manner, thereby sealing chamber 12 so that valve element 14 is arranged in chamber 12 “between” coating material inlet 2 and valve seat 16. Diaphragm 24 seals between chamber 12 and the interior of valve element 14.

The displacement of valve element 14 is controlled with a dispensing control piston 50 which is arranged in a dispensing control chamber 52 formed in nozzle body 10.

Dispensing control piston 50 has a connecting projection 51 which has at is forward end an internal thread threaded onto outer thread 44 formed on control projection 42 of sealing element 34. Accordingly, any axial displacement of dispensing control piston 50 is transferred via sealing element 34 onto valve element 14. As dispensing control piston 50 is guided in nozzle body 10, it provides a guiding effect for valve element 14.

Displacement of dispensing control piston 50 within dispensing control chamber 52 can be controlled by varying the pressure in chamber 52. To this end, a pressure connection 54 is provided (please see FIG. 1). A spring 56 is arranged in dispensing control chamber 52 on the side of dispensing control piston 50 which is opposite the side where pressure connection 54 is arranged.

For controlling the maximum displacement of dispensing control piston 50 in the direction of lifting valve element 14 from valve seat 16 (in a rearward direction), an adjustable dispensing abutment 58 is provided. Dispensing abutment 58 is formed from a screw which extends into dispensing control chamber 52. By screwing dispensing abutment 58 more or less into dispensing control chamber 52, the maximum stroke of dispensing control piston 50 can be adjusted.

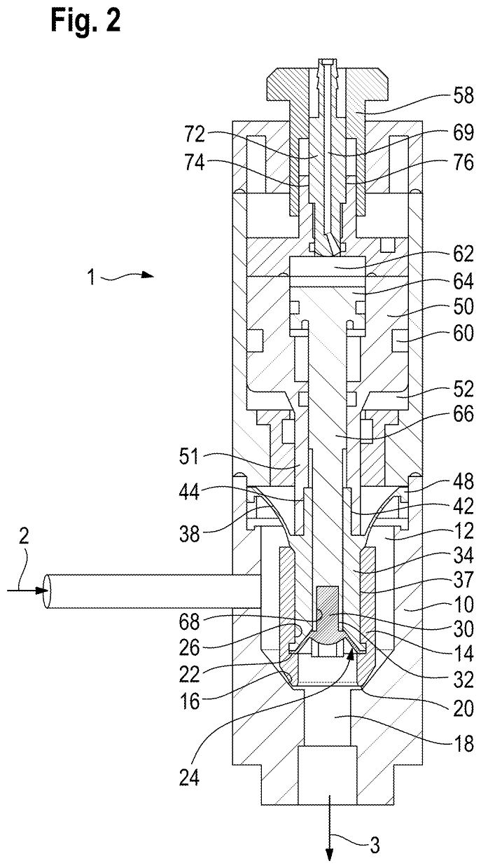

As can be seen in FIG. 2, dispensing abutment 58 can be formed hollow so as to interact with a protrusion formed on dispensing control piston 50 for achieving a guiding function.

In a known manner, a seal 60 can be used for sealing the piston 50 against dispensing control chamber 52 and nozzle body 10.

Dispensing control piston 50 is formed hollow so that a retraction control chamber 62 is formed therein. Within retraction control chamber 62, a retraction control piston 64 is arranged. It is provided with a projection 66 which has a cavity with an internal thread 68 at its forward end. Thread 68 is threaded onto thread 32 of diaphragm 24.

With retraction control piston 62, membrane 28 of diaphragm 24 can be displaced between a forward and a rearward position. As membrane 28 serves as one of the boundaries of the determined volume of the dispensing channel 18 when valve element 14 is in the closed position, retracting membrane 28 results in an increase of the volume of dispensing channel 18 whereby a small volume of coating material is being retracted into dispensing channel 18 when membrane 28 is being retracted. Because of the retracting effect which membrane 28 of diaphragm 24 exerts on the coating material, diaphragm 24 is referred to as being a retraction element.

The displacement of retraction control piston 64 within retraction control chamber 62 is controlled by varying the pressure in retraction control chamber 62. To this end, a pressure connection 69 is provided (please see FIGS. 1 and 2). A spring 70 is arranged in retraction control chamber 62 on the side of retraction control piston 64 which is opposite the side where pressure connection 69 is arranged.

Pressure connection 69 can be formed in a retraction abutment 72 which is here embodied as a hollow adjustment screw which engages with an outer thread 74 into an internal thread 76 formed in a rear portion of dispensing control piston 50. Accordingly, retraction abutment 72 moves together with dispensing control piston 50 when valve element 14 is being displaced.

Retraction control piston 64 can be displaces rearwardly (away from valve seat 16) until it abuts at retraction abutment 72. The corresponding stroke can be adjusted by screwing retraction abutment 72 more or less into the rear portion of dispensing control piston 50.

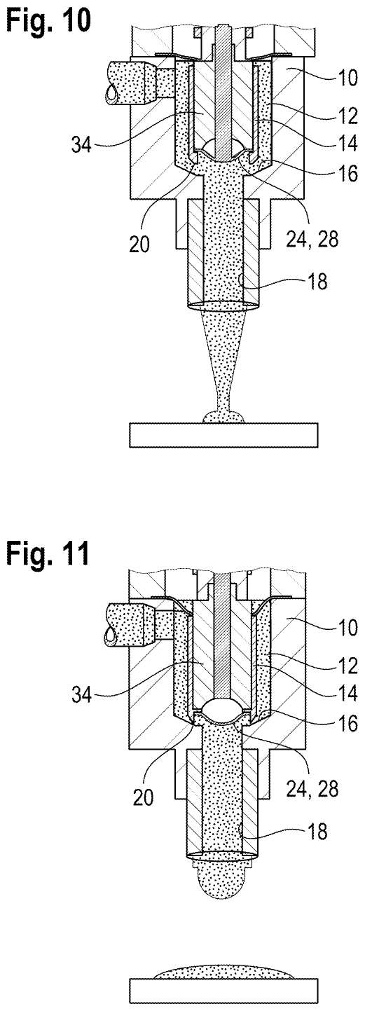

For dispensing coating material, valve element 14 is brought into an open condition by increasing the pressure in dispensing control chamber 52 to the extent that the force of spring 56 is overcome and dispensing control piston 50 is being moved in the rearward direction. Accordingly, dispensing control piston 50 lifts, via sealing element 34, valve element 14 from valve seat 16. In this condition which is shown in FIG. 10, coating material supplied via coating material inlet 2 flows through chamber 12 and exits through dispensing channel 18.

When coating material is being dispensed, diaphragm 24 is in the forward position. This is done by suitably controlling the pressure in retraction control chamber 62.

When the flow of coating material is to be stopped, the pressure in dispensing control chamber 52 is decreased so that dispensing control piston 50 is moved, by the effect of spring 56 and possibly by the pressure level applied to dispensing control chamber 52, in the forward direction until valve element 14 abuts at valve seat 16. Then, the flow of coating material is stopped. This condition is shown in FIG. 11.

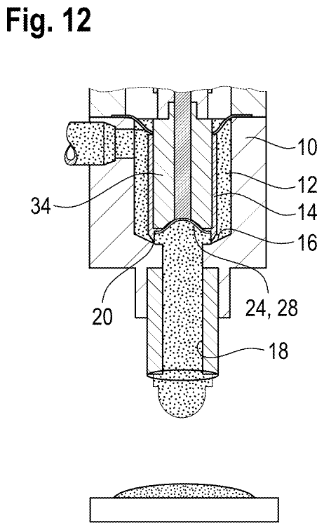

For preventing that coating material drops from the forward end of dispensing nozzle 1, a small amount of coating material is being sucked back into dispensing channel 18. This is accomplished by moving retraction element 24 from the forward position into the rearward position shown in FIG. 12. As valve element 14 contacts valve seat 16, the displacement of retraction element 24 (more specifically: of membrane 28) has an effect only on the coating material which is “downstream” of valve seat 16. Accordingly, the volume sucked back into the forward end of valve element 14 results in a small meniscus being formed at the out end of dispensing channel 18, and no coating material can drop from dispensing nozzle 1 onto the substrate to be coated.

1. A dispensing nozzle for applying a coating to a substrate, having a valve seat, a valve element adapted for being displaced between a closed position in which it interacts with the valve seat so as to close a connection between a coating material inlet and a coating material outlet of the dispensing nozzle, and an open position in which this connection is open, and further having a retraction element adapted for being displaced between a forward position and a rearward position, the retraction element being in fluid communication with a dispensing channel of the dispensing nozzle downstream of the valve element, with the retraction element being a diaphragm which on one side is exposed to the dispensing channel.

2. The dispensing nozzle of claim 1 wherein the retraction element is arranged laterally of the dispensing channel, in particular in a nozzle body of the dispensing nozzle.

3. The dispensing nozzle of claim 1 wherein the retraction element is arranged in the valve element and is in fluid connection with the dispensing channel.

4. The dispensing nozzle of claim 1 wherein the valve element is a sleeve, the diaphragm being clamped to the valve element.

5. The dispensing nozzle of claim 1 wherein a sealing element is provided which seals between the valve element and the nozzle body of the dispensing nozzle.

6. The dispensing nozzle of claim 5 wherein the valve element is a sleeve, the diaphragm being clamped to the valve element and wherein the sealing element is screwed into the valve element and clamps the diaphragm therein.

7. The dispensing nozzle of claim 1 wherein the retraction element is a piston which on one side is exposed to the dispensing channel.

8. The dispensing nozzle of claim 1 wherein a retraction control chamber is provided which is operatively connected to the retraction element.

9. The dispensing nozzle of claim 8 wherein a retraction control piston is provided which is exposed to the pressure in the retraction control chamber.

10. The dispensing nozzle of claim 9 wherein an adjustable retraction abutment is provided for adjusting the maximum stroke of the retraction control piston.

11. The dispensing nozzle of claim 9 wherein a sealing element is provided which seals between the valve element and the nozzle body of the dispensing nozzle, wherein the valve element is a sleeve, the diaphragm being clamped to the valve element, and wherein the sealing element is screwed into the valve element and clamps the diaphragm therein, the sealing element being guided on the retraction control piston.

12. The dispensing nozzle of claim 11 wherein the retraction control piston is screwed onto a protrusion of the diaphragm.

13. The dispensing nozzle of claim 1 wherein a dispensing control chamber is provided which is operatively connected to the valve element.

14. The dispensing nozzle of claim 13 wherein an adjustable dispensing abutment is provided for adjusting the maximum stroke of the valve element.
